(19) United States
(12) Patent Application Publication
(10) Pub. No.: US 2025/0067790 A1
(43) Pub. Date: Feb. 27, 2025

(54) Method for Monitoring a Drive Device of an Electric Motor

(71) Applicant: Robert Bosch GmbH, Stuttgart (DE)

(72) Inventors: Carsten Rau, Pluederhausen (DE); Patrick Messner, Goeggingen (DE); Rene Schmalzgraeber, Iggingen (DE)

(21) Appl. No.: 18/808,282

(22) Filed: Aug. 19, 2024

(30) Foreign Application Priority Data
Aug. 22, 2023 (DE) 10 2023 208 003.6

(51) Int. Cl. G01R 31/26; G01R 31/34; H02K 11/20; H02K 11/33

(52) U.S. Cl. CPC G01R 31/2642; G01R 31/343; H02K 11/20; H02K 11/33

(57) ABSTRACT

A method for monitoring a drive device of an electric motor is disclosed. A plurality of switching elements is provided in the drive device. A switching time is measured for at least one of the switching elements. And the state of the drive device is evaluated on the basis of the measured switching time.

This application claims priority under 35 U.S.C. § 119 to patent application no. DE 10 2023 208 003.6, filed on Aug. 22, 2023 in Germany, the disclosure of which is incorporated herein by reference in its entirety.

The disclosure relates to a method for monitoring a drive device of an electric motor and an arrangement for carrying out the method.

### BACKGROUND

Various devices for driving electric motors are known. In principle, such drive devices comprise an arrangement of switching elements, wherein this arrangement is also referred to as an inverter or output stage and has at least one half-bridge with a first switching element and a second switching element connected in series with the first switching element. The first switching element is typically referred to as a high-side (HS) switching element and the second switching element as a low-side (LS) switching element.

A method for operating a drive device for driving an electric motor is known from publication DE 10 2020 203 016 A1. The drive device comprises at least one half-bridge with a first switching element and a second switching element connected in series with the first switching element. The half-bridge is operated with a first dead time during a first switching operation in which the first switching element is opened and the second switching element is closed. Furthermore, the half-bridge is operated with a second dead time during a second switching operation in which the second switching element is opened and the first switching element is closed. An output current caused by the operation of the half-bridge and/or an output voltage caused by the operation of the half-bridge is monitored, wherein a first switching characteristic correlated with the switch-off time of the first switching element and/or a switch-on time of the second switching element is determined from the output current and/or the output voltage and a duration of the first dead time is dynamically adapted as a function of the first switching characteristic. Furthermore, a second switching characteristic correlated with a switch-off time of the second switching element and/or a switch-on time of the first switching element is determined from the output current and/or the output voltage and a duration of the second dead time is dynamically adapted as a function of the second switching characteristic. In particular, this can also be carried out as a function of current, voltage and/or temperature.

In modern power electronic devices, e.g. inverters or power converter or power control units, such as drivers of electric BDC motors (BDC: brushless DC: brushed DC motor), an electronic output stage is used to drive and control or regulate the currents.

One of the main problems with output stages is the high failure rate during operation, which can be caused by thermal or mechanical stress, electrical overload or ageing.

This always leads to a fault in the output stage, wherein the only reaction to this event is to initiate fault operation of the output stage or to switch off the output stage. For safety-critical applications, there is only one way to react after the fault has occurred in the output stage, which can potentially endanger the user. Therefore, the components are often oversized in order to minimize the risk of a potential hazard. However, this is associated with high costs.

Faults in the power elements or devices can only be detected if the functionality is impaired. The system can therefore only react to a fault or defect, which can lead to a potential risk for the user. A warning that the system could soon fail cannot yet be generated for the power electronics. The only option is to set up a damage counter via temperature or time or temperature strokes for the device, which can limit the operating time excessively.

In order to prevent components of the output stage, such as MOSFETs, IGBTS, etc., from overheating and therefore being destroyed, a temperature sensing component, such as a diode on the chip of the component of the output stage, or a temperature sensitive element, such as NTC, PTC, diode, etc., which is placed close to the component(s) of the output stage, is used to measure the temperature of the device, as most faults result from an overtemperature of the chip, which can be detected by such a measure. Nevertheless, not all faults can be detected by this measuring or sensing element, as it measures the temperature of the chip passively. Therefore, if only a few cells are damaged and cause a cascading fault or failure of the MOSFET, it is unlikely that the measuring element will detect the fault in advance and the system will be able to respond appropriately.

### SUMMARY

Against this background, a method and arrangement are present possessing the features set forth below. Embodiments arise from the description set forth below.

The method presented is used to monitor a drive device of an electric motor, wherein a plurality of switching elements, e.g. MOSFETs, are provided in the drive device. A switching time is then measured for at least one of the switching elements. The status of the drive device is evaluated on the basis of the measured switching time. This means, for example, that the measured switching time enables a statement to be made about the switching element whose switching time was measured and thus also about the state of the output stage in which the switching element is located and even about the state of the entire drive device. Typically, only one half-bridge can be monitored per signal.

Based on the fact that the temperature and other fault mechanisms lead to an increased switching time, the idea is to monitor the switching time of the switching elements. If the measurement of the switching time above the measured current and voltage shows a high value for the switching time, this is an indication that the MOSFET or the thermal cooling path of the MOSFET is damaged due to an increased temperature. This increased temperature can also be caused by another component.

Further advantages and embodiments of the disclosure are shown in the description and the accompanying drawings.

It is understood that the above-mentioned features and those to be explained below can be used not only in the combination indicated in each case, but also in other combinations or on their own, without departing from the scope of the present disclosure.

### BRIEF DESCRIPTION OF THE DRAWINGS

FIG. 1 shows a graph of signal courses to illustrate the HV switch-off behavior of a damaged MOSFET.

FIG. 2 shows a graph of signal courses to illustrate the HV switch-off behavior of an undamaged MOSFET.

FIG. 3 shows a switching diagram of a half-bridge with a call-off path and an entire drive device.

FIG. 4 shows a circuit diagram of a single HV/LV switch with call-off path.

FIG. 5 shows a graph of signal courses when measuring the switch-off times for an HV MOSFET/IGBT.

FIG. 6 shows in a graph, the comparison between call-off signals from a set of call-off signals against temperature.

### DETAILED DESCRIPTION

The disclosure is illustrated schematically by way of embodiments in the drawings and is described in detail below with reference to the drawings.

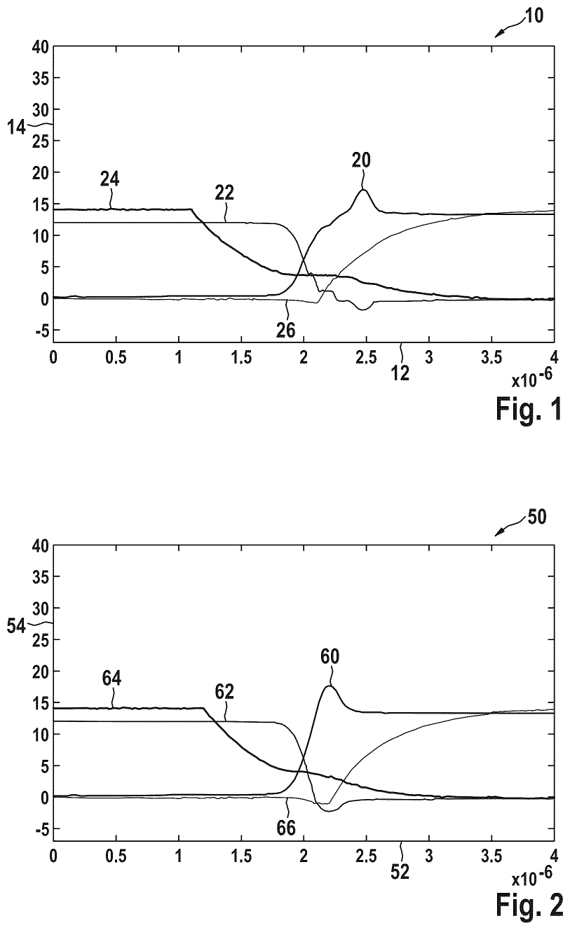

FIG. 1 shows the switching behavior of a damaged HV MOSFET in a graph 10. Said HV MOSFET is damaged, for example, due to mechanical damage, in this case due to overstressing and therefore incoming crack formation in the chip. The graph 10, whose abscissa 12 shows the time t [s] and whose ordinate 14 shows the voltage [V], shows the courses of U_{DS} 20 on the HV MOSFET, U_{DS} 22 on the LS MOSFET, U_{GS} 24 on the HV MOSFET and U_{GS} 26 on the LS MOSFET.

FIG. 2 shows the switching behavior of an undamaged HV MOSFET in a graph 50. The graph 50, whose abscissa 52 shows the time t [s] and whose ordinate 54 shows the voltage [V], shows the courses of U_{DS} 60 on the HV MOSFET, U_{DS} 62 on the LS MOSFET, U_{GS} 64 on the HV MOSFET and U_{GS} 66 on the LS MOSFET.

As can be seen, the gate plateau voltage of the damaged MOSFET increases, which leads to an increased switching time of the switching device, in this case the MOSFET.

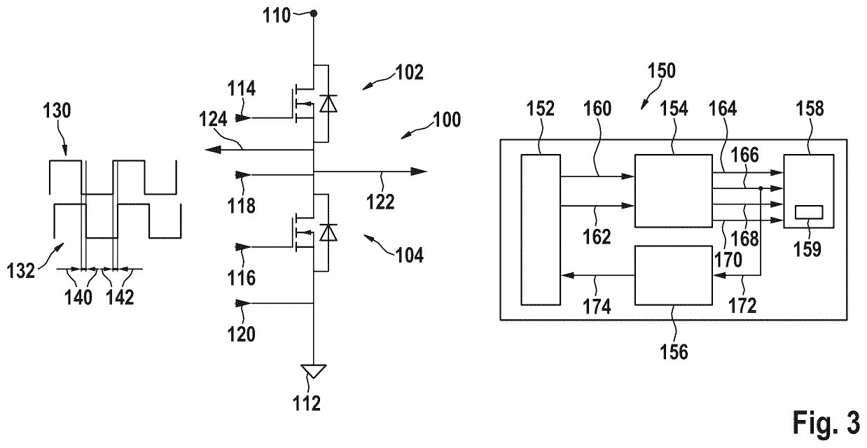

To measure the switching time, for example, the phase feedback signal or call-off path signal can be measured, which could be done with the circuit shown in FIG. 3.

FIG. 3 shows a half-bridge on the left-hand side, which is labeled with the reference number 100. This half-bridge 100 comprises an HS MOSFET 102 and an LS MOSFET 104. Furthermore, the illustration shows a terminal 110 for the battery voltage V_{BAT}, a terminal 112 for ground, a gate terminal 114 for the HV MOSFET 102, a gate terminal 116 for the LS MOSFET 104, a source terminal 118 for the HV MOSFET 102 and a source terminal 120 for the LS MOSFET 104. The MOSFETs 102, 104 thus serve as switching elements.

The illustration also shows an output 122 for the drive device to the load and an output 124 for a status feedback, the so-called call-off path 124.

A first curve 130 shows the course of a square-wave signal applied to the gate terminal 114 of the HV MOSFET 104. A further curve 132 shows the course of a square-wave signal applied to the call-off 124. Arrows 140 illustrate a time difference between the two curves 130, 132 when switching off, arrows 142 illustrate a time difference between the two curves 130, 132 when switching on.

On the right-hand side of FIG. 3, a block diagram shows a drive device for driving an electric motor, wherein the drive device as a whole is designated by the reference number 150. The drive device 150 comprises a microcontroller 152, a gate driver unit (GDU) 154, a signal conversion feedback circuit 156 and an output stage 158, in which at least one half-bridge 100 and thus switching elements 159 are provided.

Signals are a PWM signal U_{PWM,HS} 160 for the HS MOSFET, a PWM signal UPWM,LS 162 for the LS MOSFET, a signal U_{GATE,HS} 164 for the gate of the HS MOSFET, a signal U_{SOURCE, HS} 166 for the source terminal of the HS MOSFET, a signal U_{GATE,LS} 168 for the gate of the LS-MOSFET, a signal U_{SOURCE, LS} 170 for the source terminal of the LS-MOSFET, a phase signal U_{PHASE} 172, which corresponds to the signal U_{SOURCE,HS} 166 and a signal U_{PFB}, a phase read-back signal 174. This is a signal 124 adapted to logic voltage, which can have significantly higher voltages.

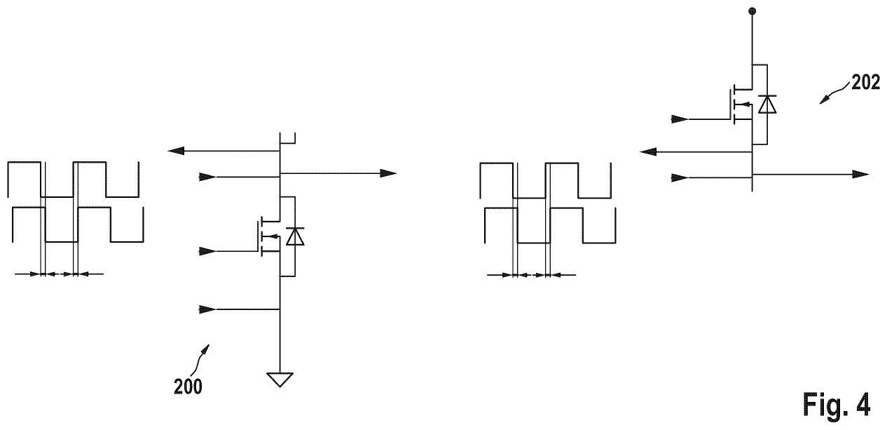

FIG. 4 shows a call-off path for a single HV/LV switch, e.g. for an n-channel MOSFET. A p-channel MOSFET can also be used. The illustration shows an LS switch 200 and an HS switch 202 with the terminals and drive signals as well as signals on the call-off path as in FIG. 3.

If a higher switching time is applied to the phase with the circuit, the measuring device, e.g. a microcontroller, can measure the switching time of the phase. Thus, if, for example, the THS_OFF time is longer than expected for the states provided, this indicates either an overtemperature or a malfunction of the device.

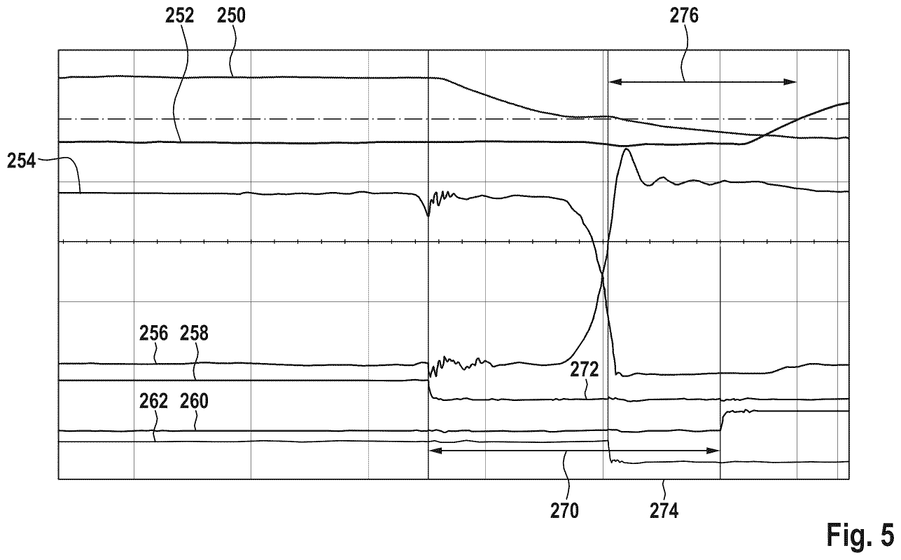

FIG. 5 shows different signal courses, namely U_{GS,HS} 250, U_{GS,LS} 252, U_{DS,LS} 254, U_{DS,HS} 256, U_{PWM,HS} 258, U_{PWM,LS} 260, U_{PFB} 262. Double arrows indicate time durations, namely a set dead time T_{Dead,set} 270, a time T_{HS,off} 272, a time T_{LS,on} 274 and an unused dead time T_{Dead,unused} 276.

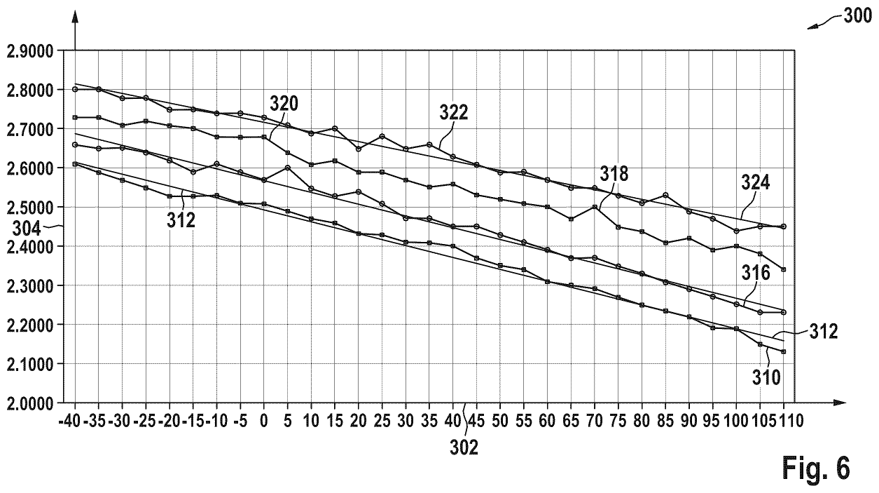

Therefore, the measuring device, e.g. a microcontroller, which controls the inverter, is able to detect a fault before it leads to a complete failure of the inverter and suitable counter measures can be taken. The overtemperature can be detected due to the fact that the threshold voltage increases above the temperature and the resulting increase in switching time can be measured or estimated at the same current and voltage, which can be seen in the graph in FIG. 6.

FIG. 6 shows in a graph 300, on the abscissa 302 of which the temperature [C] is plotted and on the ordinate 304 of which the switching time difference [%] is plotted, a comparison between call-off signals over the temperature, wherein in each case the course of the determined values together with the course of a linear interpolation is shown

The illustration shows a first course 310 at a difference of 1 A with the course 312 of the interpolation, a second course 314 at a difference of 2 A with the course 316 of the interpolation, a third course 318 at a difference of 5 A with the course 320 of the interpolation and a fourth course 322 at a difference of 10 A with the course 324 of the interpolation.

The fault or overtemperature can thus be detected if the measured switching time exceeds the calculated switching time at a maximum permitted temperature. For example, a switching time of 850 ns at a current of 50 A and a drain-source voltage of 13 V at a temperature of 175° C. is calculated. If the measured switching time under these conditions is higher than these 850 ns, this is an indication that the switching device is overheated or damaged.

It is now possible to warn the user of the faulty device so that a potentially dangerous situation can be prevented before the device fails completely. It is also possible to put the device into emergency mode before the defect occurs.

Some definitions are given below:

The switching time is the period of time, the propagation delay, between the sending of a command to the input of the output stage, i.e. a signal change at the gate, and the time at which the output Ups, i.e. the drain-source voltage, changes.

The time between switching the half-bridges with: UDS_Highside-off and UDS_Lowside-on is referred to as the dead time of the falling edge and UDS_Highside_off and UDS_Highside_on are described as the dead time of the rising edge.

The basic idea is to calibrate the switching time of each MOSFET/IGBT of the power device once at a specified current(s), voltage(s) and chip temperature(s) and to recalculate or determine the switching time(s) of the power device(s) permanently or occasionally during normal operation.

To evaluate the switching time from the feedback signal, a known current must flow:
into the output stage to measure the switch-on and switch-off time of the LS switch,
from the output stage to measure the switch-on and switch-off time of the HV switch.

The known current required can be generated by the output stage itself or by an external source. The applied voltage can also be measured to increase accuracy.

### Requirements for the Half-Bridges

The dead time between HV and LS switching is set to more than the required minimum dead time.

The dead time for the falling edge and the dead time for the rising edge should be determined separately for each half-bridge.

### Requirements

The switching time of the MOSFET/IGBT should be determined at least at one temperature. This can also be carried out at a range of temperatures. This/These measurement(s) is/are used as reference value(s).

The switching times of the MOSFET/IGBT should be determined at least at one current. This can also be done for a range of currents. This/These measurement(s) is/are used as reference value(s).

The switching times of the MOSFET/IGBT should be determined for at least one voltage. It is also possible to do this for a range of voltages. This/These measurement(s) is/are used as reference value(s).

A phase feedback signal should be provided for the logic. This should be done for a comparator, for example, in order to make it readable for the internal measuring device, e.g. for a microcontroller, etc.

The differences between the set signal and the signal read back are measured, e.g. with a microcontroller.

The switching time is the time, propagation delay, from sending a command to the input of the output stage, i.e. signal change at the gate, until the load voltage changes.

Advantages of the method compared to previous solutions are:

Earlier solutions can only detect an excess temperature in switching devices by measuring the temperature of the switching element with a separate measuring device.

Known systems can only detect a fault if the device has failed and the system is affected. It is now possible to record components that are about to be damaged.

The new procedure makes it possible to detect faults before the disruptive effects occur in the system.

This makes it possible to initiate suitable countermeasures before a system malfunction can pose a potential risk to the user.

Ageing effects of the thermal connection between each individual component of the output stage and heat sinks can be recorded by comparison with a temperature model over the lifetime.

Early warnings of the end of operation can be generated.

Safety margins due to oversizing can be reduced to a minimum value.

No fault counter is to be implemented, which limits the service life excessively.

Increased security for the user and increased system availability are achieved.

More fault modes can be detected than if the temperature alone is used.

General advantages of the method regardless of the internal or external sensor used:

A digital measurement of feedback signal edges instead of signals with small levels and high impedances of analog heat sensors is possible, e.g. a measurement of the parasitic body diode. This is also robust in terms of electromagnetic compatibility.

The method is applicable to each individual power device in each half-bridge B2, B4, B6, . . . , or individual circuit breaker if phase/load feedback monitoring is implemented.

A simple measuring circuit can be used.

What is claimed is:

1. A method for monitoring a drive device of an electric motor, comprising:
providing a plurality of switching elements in the drive device;
measuring a switching time for at least one of the switching elements; and
evaluating a state of the drive device on the basis of the measured switching time.

2. The method according to claim 1, further comprising detecting a fault in the drive device.

3. The method according to claim 2, further comprising warning a user in response to detecting a fault.

4. The method according to claim 2, further comprising initiating an emergency mode in response to detecting a fault.

5. The method according to claim 1, further comprising carrying out a comparison of the measured switching time with another time.

6. The method according to claim 5, wherein the other time is determined by a calculation.

7. The method according to claim 1, further comprising determining the switching time via a measured call-off path signal.

8. The method according to claim 7, wherein the determined switching time is considered over a measured current and a measured voltage.

9. The method according to claim 1, wherein MOSFETs are used as the switching elements.

10. An arrangement for monitoring a drive device of an electric motor, which is arranged to carry out a method according to claim 1.
